(19) United States
(12) Patent Application Publication
(10) Pub. No.: US 2024/0063244 A1
(43) Pub. Date: Feb. 22, 2024

(54) SEMICONDUCTOR PACKAGE, ELECTRONIC DEVICE, AND METHOD OF MANUFACTURING SEMICONDUCTOR PACKAGE

(71) Applicant: SONY SEMICONDUCTOR SOLUTIONS CORPORATION, KANAGAWA (JP)

(72) Inventor: TOSHIKI KOYAMA, KANAGAWA (JP)

(21) Appl. No.: 18/260,673

(22) PCT Filed: Nov. 19, 2021
(86) PCT No.: PCT/JP2021/042573

§ 371 Date: Jul. 7, 2023

(30) Foreign Application Priority Data
Jan. 15, 2021 (JP) 2021-005212

(51) Int. Cl. H01L 27/146

(52) U.S. Cl. CPC H01L 27/14634; H01L 27/14636; H01L 27/1469; H01L 27/14632; H01L 27/14687

(57) ABSTRACT

The number of components of a semiconductor package is reduced. The semiconductor package includes a solid-state imaging element, a frame, and an adhesive. In the semiconductor package, the solid-state imaging element has a pixel region in which pixels are arrayed and a circuit region in which a predetermined circuit is arranged adjacent to the pixel region. In the semiconductor package, an inner wall of the frame surrounds an outer periphery of the solid-state imaging element, and a part of the inner wall is extended inward. In the semiconductor package, the adhesive bonds the extended portion of the frame and the circuit region.

### TECHNICAL FIELD

The present technology relates to a semiconductor package. Specifically, the present technology relates to a semiconductor package that generates image data, an electronic device, and a method of manufacturing the semiconductor package.

### BACKGROUND ART

A semiconductor package in which a semiconductor integrated circuit is mounted on a substrate and is sealed has been conventionally used for the purpose of, for example, facilitating handling of the semiconductor integrated circuit. For example, there is proposed a semiconductor package obtained by mounting a solid-state imaging element as a semiconductor integrated circuit inside a frame member, covering a portion other than a light receiving surface of the solid-state imaging element with a heat dissipation plate or a heat dissipation sheet, and sealing the solid-state imaging element with glass (see, for example, Patent Document 1).

### CITATION LIST

### Patent Document

Patent Document 1: Japanese Patent Application Laid-Open No. 2007-158184

### SUMMARY OF THE INVENTION

### Problems to be Solved by the Invention

In the above related art, heat generated in the solid-state imaging element is dissipated by covering the portion other than the light receiving surface of the solid-state imaging element with the heat dissipation plate or the like. However, in the above semiconductor package, the number of components increases due to the heat dissipation plate or the heat dissipation sheet. When the number of components increases, the manufacturing cost may increase, and reduction in size of the semiconductor package may become difficult.

The present technology has been made in view of such a situation, and an object thereof is to reduce the number of components of a semiconductor package.

### Solutions to Problems

The present technology has been made to solve the above problems, and a first aspect thereof is a semiconductor package and a manufacturing method thereof, the semiconductor package including: a solid-state imaging element having a pixel region in which pixels are arrayed and a circuit region in which a predetermined circuit is arranged adjacent to the pixel region; a frame whose inner wall surrounding an outer periphery of the solid-state imaging element is partially extended inward; and an adhesive for bonding the extended portion of the frame to the circuit region. Therefore, it is possible to reduce the number of components of the semiconductor package.

Further, in the first aspect, a substrate and a predetermined number of wires that connect the substrate and the solid-state imaging element may be further included. Therefore, it is possible to electrically connect the substrate and the solid-state imaging element.

Further, in the first aspect, the frame may cover some of the wires and the circuit region. Therefore, it is possible to dissipate heat generated in the circuit region.

Further, in the first aspect, the frame may further cover the remaining wires. Therefore, it is possible to block unnecessary light.

Further, in the first aspect, the extended portion of the frame may have a tapered end surface. Therefore, it is possible to suppress flares.

Further, a second aspect of the present technology is an electronic device including: a solid-state imaging element having a pixel region in which pixels are arrayed and a circuit region in which a predetermined circuit is arranged adjacent to the pixel region; a frame whose inner wall surrounding an outer periphery of the solid-state imaging element is partially extended inward; an adhesive for bonding the extended portion of the frame and the circuit region; and an optical unit that collects light and guides the light to the solid-state imaging element. Therefore, it is possible to reduce the number of components of the electronic device.

### BRIEF DESCRIPTION OF DRAWINGS

FIG. 1 is a block diagram illustrating a configuration example of an electronic device according to a first embodiment of the present technology.

FIG. 2 is an example of a cross-sectional view of a semiconductor package according to the first embodiment of the present technology.

FIG. 3 is an example of an enlarged view of the semiconductor package according to the first embodiment of the present technology.

FIG. 4 is an example of a plan view of the semiconductor package according to the first embodiment of the present technology.

FIG. 5 is an example of a cross-sectional view of a semiconductor package in a comparative example.

FIG. 6 is an example of a plan view of a semiconductor package in a comparative example.

FIG. 7 illustrates an example of a heat dissipation path of the semiconductor package according to the first embodiment of the present technology.

FIG. 8 is an example of a cross-sectional view illustrating a method of manufacturing the semiconductor package up to wire bonding in the first embodiment of the present technology.

FIG. 9 is an example of a cross-sectional view illustrating the method of manufacturing the semiconductor package up to bonding of glass in the first embodiment of the present technology.

FIG. 10 is an example of a plan view illustrating the method of manufacturing the semiconductor package up to the wire bonding in the first embodiment of the present technology.

FIG. 11 is an example of a plan view illustrating the method of manufacturing the semiconductor package up to the bonding of glass in the first embodiment of the present technology.

FIG. 12 is a flowchart showing an example of the method of manufacturing the semiconductor package in the first embodiment of the present technology.

FIG. 13 is an example of a plan view of a semiconductor package in a first modification example of the first embodiment of the present technology.

FIG. 14 is an example of a cross-sectional view of a semiconductor package according to a second modification example of the first embodiment of the present technology.

FIG. 15 is an example of a cross-sectional view of a semiconductor package according to a second embodiment of the present technology.

FIG. 16 is an example of a plan view of the semiconductor package according to the second embodiment of the present technology.

FIG. 17 is an example of a cross-sectional view of a semiconductor package according to a third embodiment of the present technology.

FIG. 18 is an example of a cross-sectional view of a semiconductor package according to a fourth embodiment of the present technology.

FIG. 19 is an example of a cross-sectional view of a semiconductor package according to a fifth embodiment of the present technology.

FIG. 20 is an example of a cross-sectional view of a semiconductor package according to a sixth embodiment of the present technology.

FIG. 21 illustrates an example of a heat dissipation path of the semiconductor package according to the sixth embodiment of the present technology.

FIG. 22 is an example of a plan view of the semiconductor package according to the sixth embodiment of the present technology.

FIG. 23 is another example of the plan view of the semiconductor package according to the sixth embodiment of the present technology.

FIG. 24 is an example of a cross-sectional view illustrating a method of manufacturing the semiconductor package up to mounting of a heat dissipation sheet in the sixth embodiment of the present technology.

FIG. 25 is an example of a cross-sectional view illustrating the method of manufacturing the semiconductor package up to bonding of glass in the sixth embodiment of the present technology.

FIG. 26 is an example of a plan view illustrating the method of manufacturing the semiconductor package up to wire bonding in the sixth embodiment of the present technology.

FIG. 27 is an example of a plan view illustrating the method of manufacturing the semiconductor package up to mounting of a frame in the sixth embodiment of the present technology.

FIG. 28 is an example of a cross-sectional view illustrating the method of manufacturing the semiconductor package at the time of bonding glass in the sixth embodiment of the present technology.

FIG. 29 is an example of a cross-sectional view of a semiconductor package according to a first modification example of the sixth embodiment of the present technology.

FIG. 30 is an example of a plan view of a semiconductor package according to a second modification example of the sixth embodiment of the present technology.

FIG. 31 is an example of a plan view of the semiconductor package including one heat dissipation sheet in the second modification example of the sixth embodiment of the present technology.

FIG. 32 is another example of the plan view of the semiconductor package according to the second modification example of the sixth embodiment of the present technology.

FIG. 33 is an example of a cross-sectional view of a semiconductor package according to a seventh embodiment of the present technology.

FIG. 34 is a block diagram illustrating a schematic configuration example of a vehicle control system.

FIG. 35 is an explanatory diagram illustrating an example of an installation position of an imaging section.

### MODE FOR CARRYING OUT THE INVENTION

Hereinafter, modes for carrying out the present technology (hereinafter, referred to as embodiments) will be described. Description will be made in the following order.
1. First embodiment (example of extending a part of an inner wall of a frame)
2. Second embodiment (example of extending a part of an inner wall of a frame and bonding the part to a circuit chip)
3. Third embodiment (example of extending a metal portion of a frame)
4. Fourth embodiment (example of bonding a heat dissipation sheet to a circuit chip)
5. Fifth embodiment (example where a heat dissipation sheet having one end reaching outside of a frame is bonded to a circuit chip)
6. Sixth embodiment (example where a heat dissipation sheet having one end bonded to a substrate is bonded to a circuit chip)
7. Seventh embodiment (example where a heat dissipation sheet having one end bonded to a ceramic substrate is bonded to a circuit chip)
8. Application example to mobile body

### 1. First Embodiment

### Configuration Example of Electronic Device

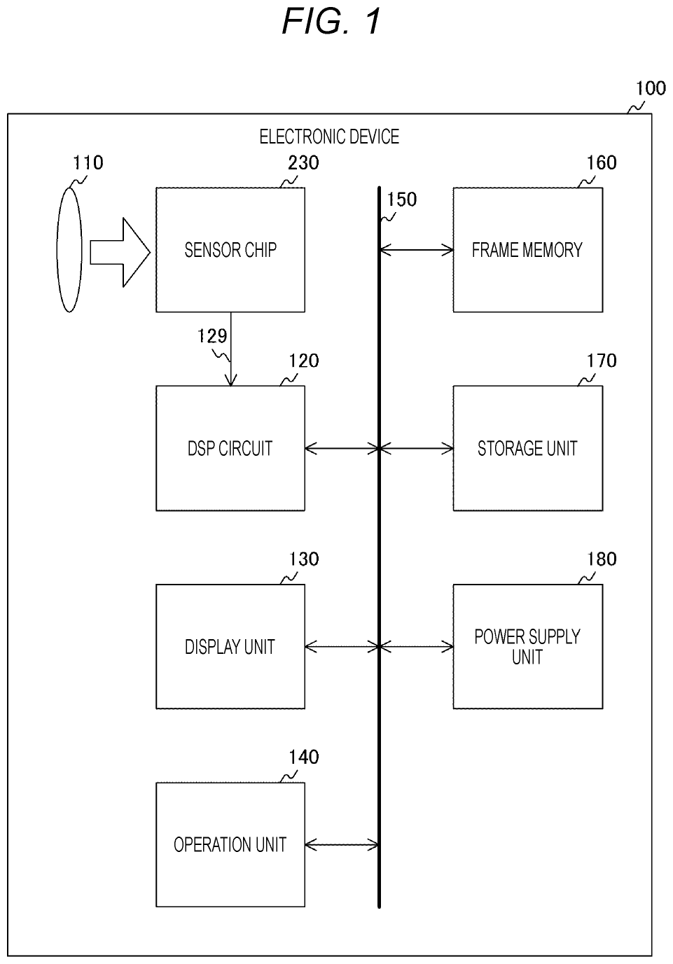

FIG. 1 is a block diagram illustrating a configuration example of an electronic device 100 according to a first embodiment of the present technology. The electronic device 100 is a device for capturing image data and includes an optical unit 110, a sensor chip 230, and a digital signal processing (DSP) circuit 120. The electronic device 100 further includes a display unit 130, an operation unit 140, a bus 150, a frame memory 160, a storage unit 170, and a power supply unit 190. The electronic device 100 is assumed to be, for example, a digital camera such as a digital still camera, a smartphone, a personal computer, an in-vehicle camera, or the like.

The optical unit 110 collects light from a subject and guides the light to the sensor chip 230. The sensor chip 230 generates image data by photoelectric conversion in synchronization with a vertical synchronization signal. Here, the vertical synchronization signal is a periodic signal of a predetermined frequency indicating an imaging timing. The sensor chip 230 supplies the generated image data to the DSP circuit 120. The sensor chip 230 is, for example, a CMOS image sensor (CIS). Note that the sensor chip 230 is an example of a solid-state imaging element recited in claims.

The DSP circuit 120 performs predetermined signal processing on the image data from the sensor chip 230. The DSP circuit 130 outputs the processed image data to the frame memory 170 or the like via the bus 160.

The display unit 130 displays the image data. The display unit 130 is assumed to be, for example, a liquid crystal panel or an organic electro luminescence (EL) panel. The operation unit 140 generates an operation signal in response to a user operation.

The bus 150 is a common path through which the optical unit 110, the sensor chip 230, the DSP circuit 120, the display unit 130, the operation unit 140, the frame memory 160, the storage unit 170, and the power supply unit 180 exchange data with each other.

The frame memory 160 holds the image data. The storage unit 170 stores various types of data such as the image data. The power supply unit 180 supplies power to the sensor chip 230, the DSP circuit 120, the display unit 130, and the like.

In the above configuration, for example, the sensor chip 230 is mounted in a semiconductor package.

### Configuration Example of Semiconductor Package

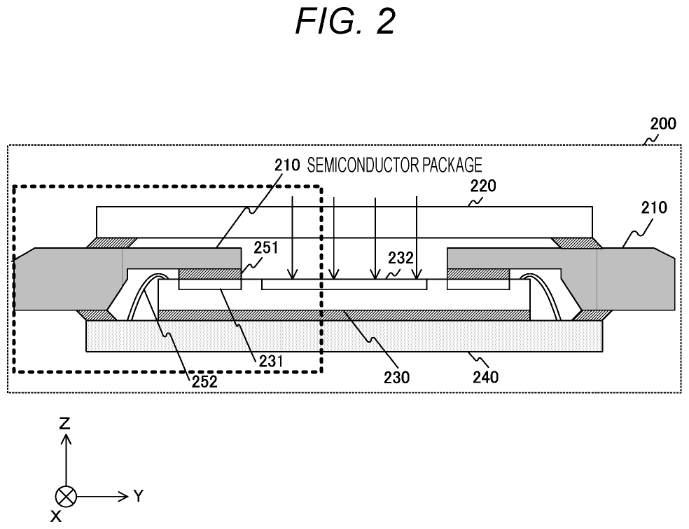

FIG. 2 is an example of a cross-sectional view of a semiconductor package 200 according to the first embodiment of the present technology. The semiconductor package 200 includes a frame 210, glass 220, the sensor chip 230, and a substrate 240. In FIG. 2, hatched portions indicate adhesives. Further, arrows indicate an incident direction of incident light from the optical unit 110 (not illustrated).

Hereinafter, an axis parallel to an optical axis is defined as a Z-axis, and a predetermined axis perpendicular to the Z-axis is defined as an X-axis. An axis perpendicular to the X-axis and the Z-axis is defined as a Y-axis. Further, a direction toward the optical unit 110 is defined as an upward direction. FIG. 2 is a cross-sectional view seen from the X-axis direction.

The sensor chip 230 is placed on an upper surface of the substrate 240 and is electrically connected to the substrate 240 by wires 252. The substrate 240 is an organic substrate or the like. Further, a pixel region 232 in which pixels are arrayed and a circuit region 231 that is adjacent to the pixel region 232 and in which a predetermined circuit is arranged are provided on an upper surface (in other words, a light receiving surface) of the sensor chip 230.

In the circuit region 231, for example, a drive circuit that drives the pixels and a signal processing circuit that processes pixel signals from the pixels are arranged.

The frame 210 is a frame-like member used to seal the sensor chip 230 together with the substrate 240 and the glass 220. The frame 210 is made from resin or the like. Details of a shape of the frame 210 will be described later. The glass is provided on the frame 210.

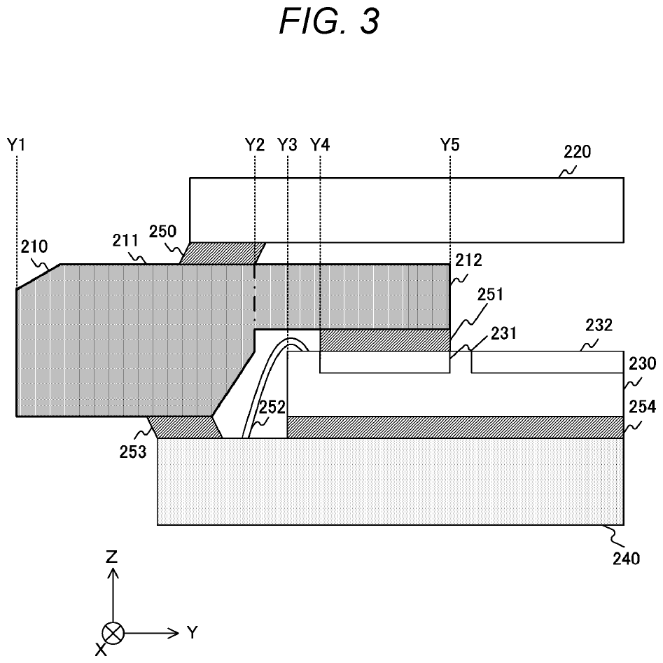

FIG. 3 is an example of an enlarged view of the semiconductor package 200 according to the first embodiment of the present technology. FIG. 3 is an enlarged view of a left part surrounded by a dotted line in FIG. 2. A part of an upper surface of the frame 210 and the glass 220 are bonded with an adhesive 250. A part of a lower surface of the frame 210 and the substrate 240 are bonded with an adhesive 253. A lower surface of the sensor chip 230 and the substrate 240 are bonded with an adhesive 254. Note that an enlarged view of a right part of the semiconductor package 200 is bilaterally symmetrical with FIG. 3.

An inner wall of the frame 210 surrounds an outer periphery of the sensor chip 230, and a part thereof is extended inward (right side in FIG. 3). The inward-extended portion of the frame 210 will be hereinafter referred to as an “extended portion 212”, and the remaining portion will be referred to as an “outer peripheral portion 211”. The outer peripheral portion 211 and the extended portion 212 are not formed by connecting separate members, but are integrally formed.

For example, a coordinate Y1 is defined as a left end of the frame 210 in the Y-axis direction. A coordinate Y3 is defined as a left end of the sensor chip 230. A pad (not illustrated) for connecting the wire 252 is provided between the coordinate Y3 and a coordinate Y4. Further, the coordinate Y4 to a coordinate Y5 are defined as the circuit region 231. Note that, in FIG. 3, a region of the frame 210 from the coordinate Y4 to the coordinate Y5 is bonded, but it is unnecessary to bond the entire region, and only a part thereof may be bonded.

The coordinate Y2 between the coordinates Y1 and Y3 is a position of the inner wall of the frame 210. A part of the inner wall is extended to the coordinate Y5. A portion of the frame 210 from the coordinate Y2 to the coordinate Y5 corresponds to the extended portion 212, and a portion thereof from the coordinate Y1 to the coordinate Y2 corresponds to the outer peripheral portion 211.

As illustrated in FIG. 3, the inner wall at the coordinate Y2 surrounds the outer periphery of the sensor chip 230 at the coordinate Y3. Further, the extended portion 212 is extended from the outer peripheral portion 211 to a position covering the entire circuit region 231 (i.e. the coordinate Y5). The extended portion 212 and the circuit region 231 are bonded with an adhesive 251.

A part of the inner wall of the frame 210 is extended to the circuit region 231, and the extended portion 212 and the circuit region 231 are bonded to each other, and thus heat generated in the circuit region 231 can be dissipated via the frame 210. The thermal conductivity of the frame 210 is desirably higher than the thermal conductivity of the substrate 240.

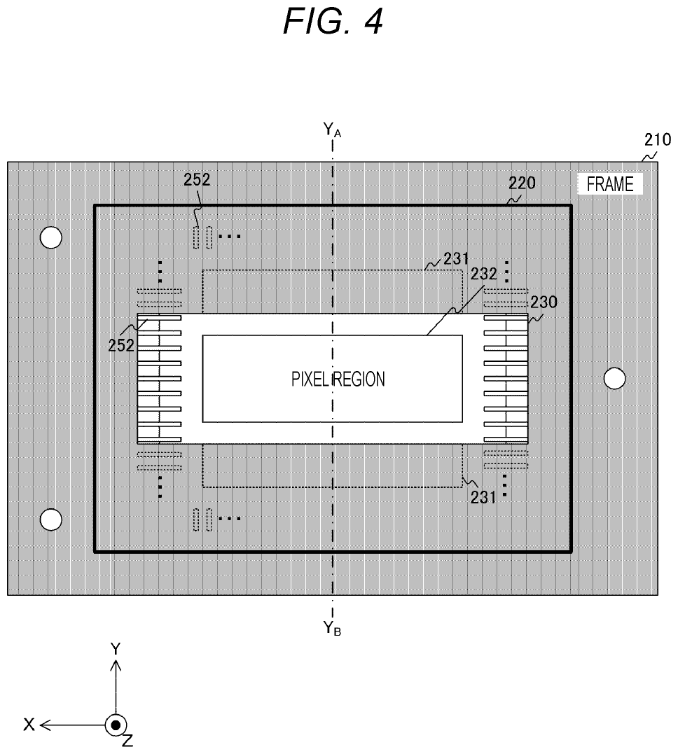

FIG. 4 is an example of a plan view of the semiconductor package 200 according to the first embodiment of the present technology. FIG. 4 is a plan view seen from the Z-axis direction. In FIG. 4, a gray portion is the upper surface of the frame 210. A thick solid line indicates an outer periphery of the glass 220. Dotted lines indicate the circuit regions 231 and the wires 252 under the frame 210. Further, a cross-sectional view of the semiconductor package 200 taken along the line segment Y_{A}-Y_{B} in FIG. 4 corresponds to FIG. 2.

Further, as illustrated in FIG. 4, the frame 210 covers some of the wires 252 and the circuit regions 231 indicated by the dotted lines as seen from the Z-axis direction. Further, a center portion of the frame 210 is open, and the remaining wires 252 and the pixel region 232 are arranged in the opening.

Here, the semiconductor package 200 in which the frame 210 has no extended portion 212 is assumed as a comparative example.

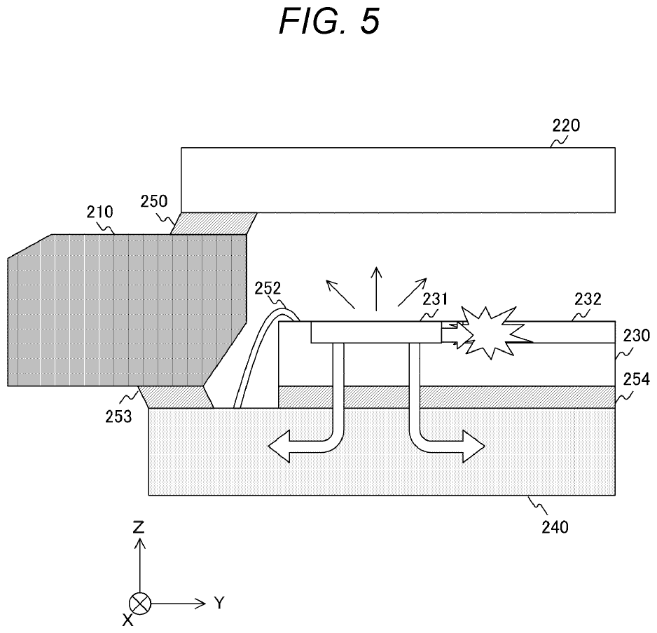

FIG. 5 is an example of a cross-sectional view of the semiconductor package 200 in the comparative example. Arrows in FIG. 5 indicate a heat dissipation path. In the comparative example where no extended portion 212 is provided, the frame 210 and the circuit region 231 are not in contact with each other. Thus, when the circuit region 231 generates heat during operation, the heat is mainly dissipated to the substrate 240. At this time, if a heat dissipation amount is not sufficient, the heat generated in the circuit region 231 may be conducted to the pixel region 232, which may cause noise in pixel signals. Therefore, image quality of image data may deteriorate.

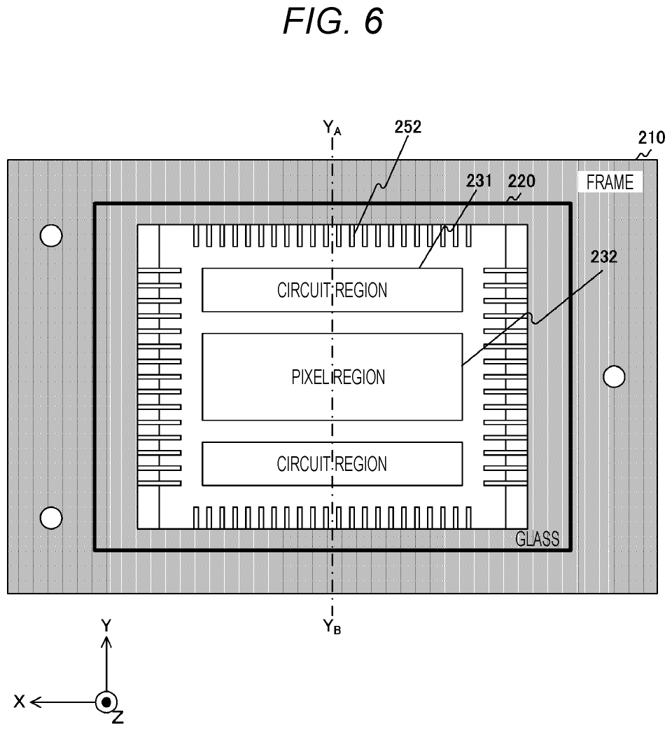

FIG. 6 is an example of a plan view of the semiconductor package in the comparative example. As illustrated in FIG. 6, in the comparative example, the pixel region 232, all the wires 252, and the circuit regions 231 are not covered with the frame 210. Therefore, as described above, heat is not conducted from the circuit region 231 to the frame 210 without passing through the substrate 240, and the heat generated in the circuit region 231 is mainly dissipated through the substrate 240.

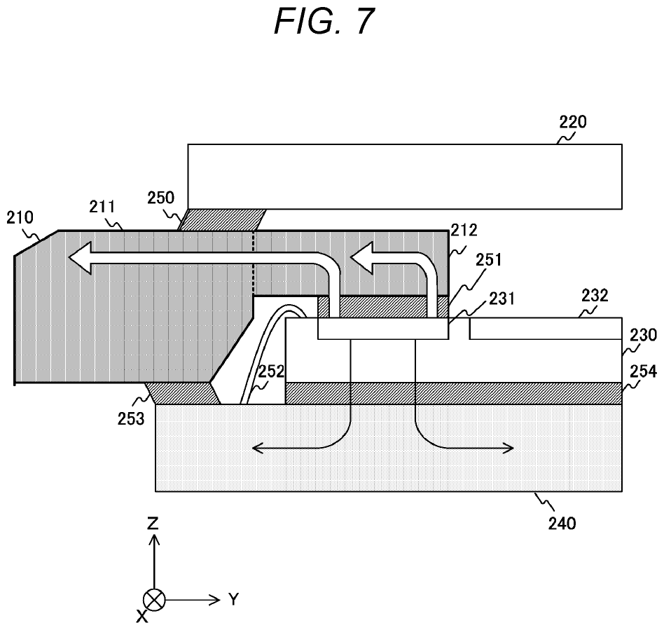

FIG. 7 illustrates an example of a heat dissipation path of the semiconductor package 200 according to the first embodiment of the present technology. As illustrated in FIG. 7, the extended portion 212 is provided in the frame 210, and thus heat can be dissipated through both the substrate 240 and the frame 210. Therefore, heat dissipation performance can be improved, as compared with the comparative example. Because the heat dissipation performance is improved, it is possible to prevent deterioration in image quality due to conduction of heat to the pixels.

Note that, in the comparative example, the heat dissipation performance can be improved by adding a heat dissipation plate or heat dissipation sheet covering the circuit regions 231. However, in that case, the manufacturing cost may increase due to an increase in the number of components such as the heat dissipation plate, and reduction in size may be difficult.

Meanwhile, in a case where a part of the frame 210 is extended, it is unnecessary to add a heat dissipation plate or the like. Thus, the number of components can be reduced accordingly. This makes it possible to suppress an increase in manufacturing cost and to easily reduce the size.

[Method of Manufacturing Semiconductor Package]

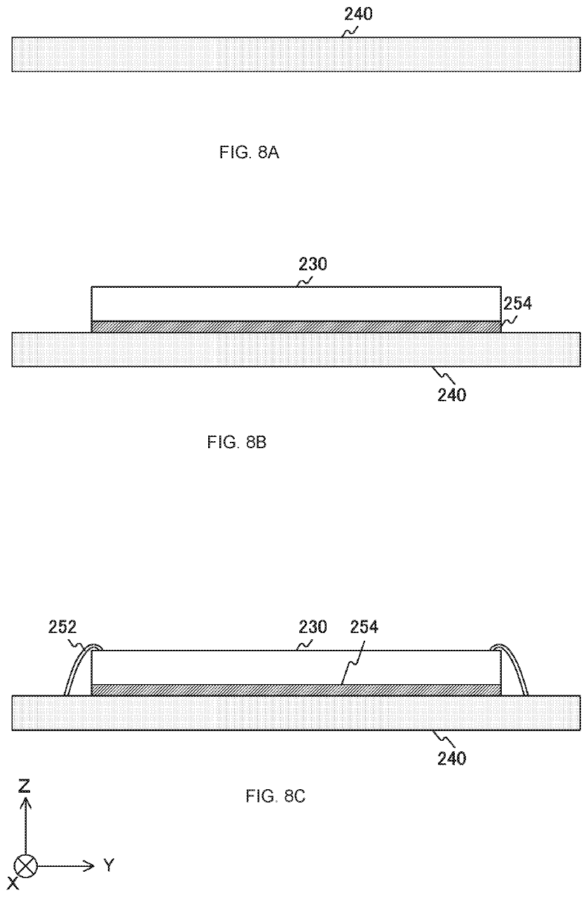

FIG. 8 is an example of a cross-sectional view illustrating a method of manufacturing the semiconductor package up to wire bonding in the first embodiment of the present technology. In FIG. 8, a is an example of a cross-sectional view of the substrate 240 before bonding the sensor chip 230. In FIG. 8, b is an example of a cross-sectional view of the semiconductor package 200 after bonding the sensor chip 230 and before wire bonding. In FIG. 8, c is an example of a cross-sectional view of the semiconductor package 200 after the wire bonding.

As illustrated in a and b of FIG. 8, a manufacturing system applies the adhesive 254 to the substrate 240 to bond the sensor chip 230. Then, as illustrated in c of FIG. 8, the manufacturing system electrically connects the substrate 240 and the sensor chip 230 by the wires 252.

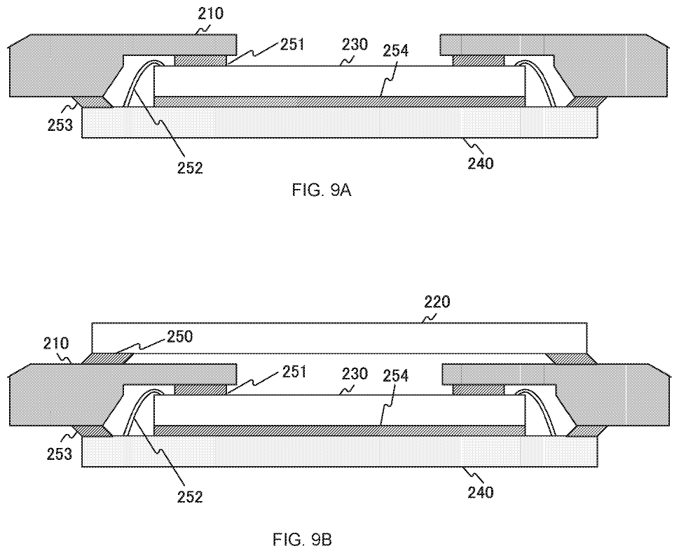

FIG. 9 is an example of a cross-sectional view illustrating the method of manufacturing the semiconductor package up to bonding of the glass 220 in the first embodiment of the present technology. In FIG. 9, a is an example of a cross-sectional view of the semiconductor package 200 after bonding the frame 210 and before bonding the glass 220. In FIG. 9, b is an example of a cross-sectional view of the semiconductor package 200 after bonding the glass 220.

As illustrated in a of FIG. 9, the manufacturing system applies the adhesives 251 and 253 to the sensor chip 230 and the substrate 240 and mounts the frame 210 whose inner wall is partially extended on the substrate 240.

Then, as illustrated in b of FIG. 9, the manufacturing system applies the adhesive 250 to the frame 210 and mounts the glass 220 thereon.

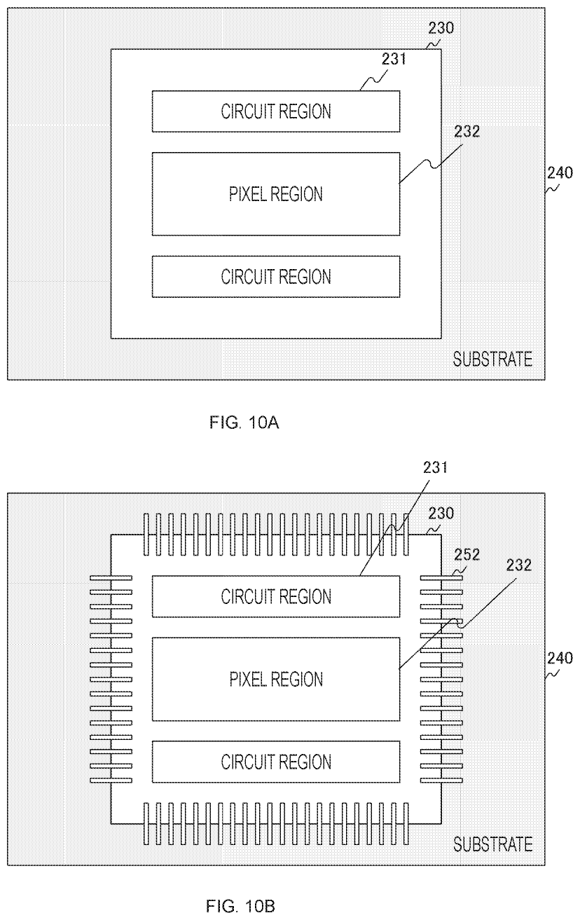

FIG. 10 is an example of a plan view illustrating the method of manufacturing the semiconductor package up to the wire bonding in the first embodiment of the present technology. In FIG. 10, a is an example of a plan view of the semiconductor package 200 after bonding the sensor chip 230 and before the wire bonding. In FIG. 10, b is an example of a plan view of the semiconductor package 200 after the wire bonding.

As illustrated in a of FIG. 10, the manufacturing system bonds the sensor chip 230 to the substrate 240. Then, as illustrated in b of FIG. 10, the manufacturing system electrically connects the substrate 240 and the sensor chip 230 by the wires 252.

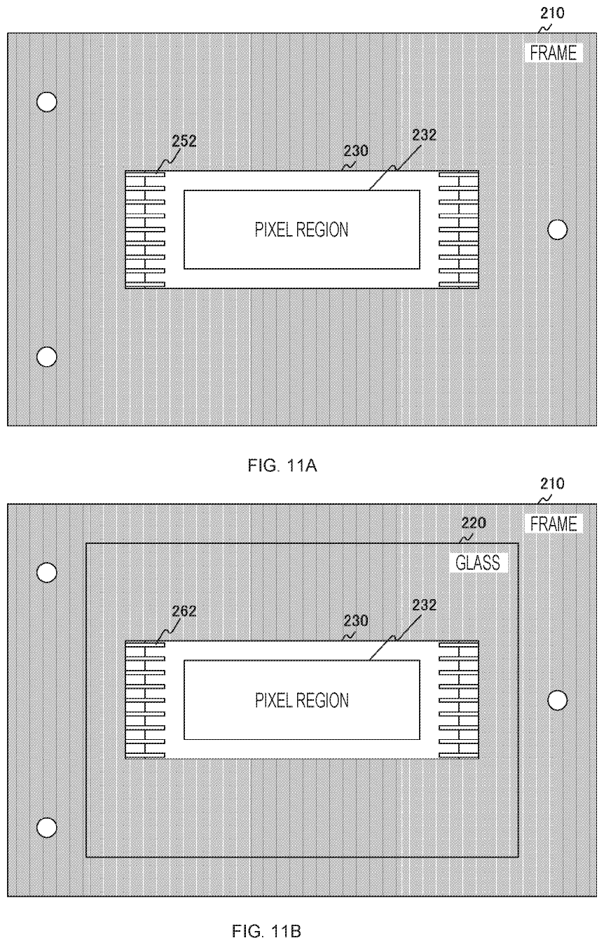

FIG. 11 is an example of a plan view illustrating the method of manufacturing the semiconductor package up to the bonding of the glass in the first embodiment of the present technology. In FIG. 11, a is an example of a plan view of the semiconductor package 200 after bonding the frame 210 and before bonding the glass 220. In FIG. 11, b is an example of a plan view of the semiconductor package 200 after bonding the glass 220.

As illustrated in a of FIG. 11, the manufacturing system bonds the sensor chip 230 and the substrate 240 to the frame 210.

Then, as illustrated in b of FIG. 11, the manufacturing system bonds the glass 220 to the frame 210.

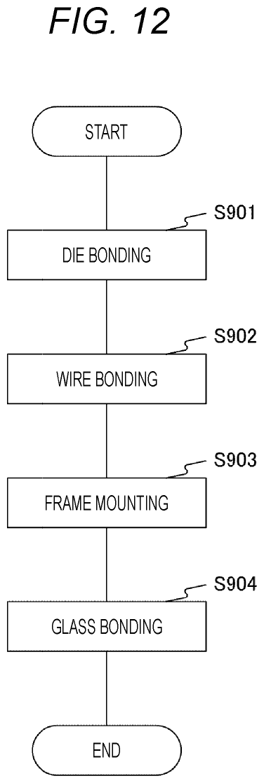

FIG. 12 is a flowchart showing an example of the method of manufacturing the semiconductor package in the first embodiment of the present technology. The manufacturing system performs a die bonding process of bonding the sensor chip 230 to the substrate 240 (step S901). Then, the manufacturing system performs a wire bonding process of electrically connecting the substrate 240 and the sensor chip 230 by wires (step S902).

Then, the manufacturing system performs a frame mounting process of mounting the frame 210 on the substrate 240 (step S903) and performs a glass bonding process of bonding the glass 220 to the frame 210 (step S904). Thereafter, the manufacturing system ends the manufacturing process of the semiconductor package 200.

As described above, in the first embodiment of the present technology, a part of the inner wall of the frame 210 is extended, and the extended portion is bonded to the circuit region 231 with the adhesive 251. Thus, heat of the circuit region 231 is dissipated through the frame 210. Therefore, components such as a heat dissipation plate are not required, which makes it possible to reduce the number of components.

### First Modification Example

In the above first embodiment, the frame 210 covers only some of the predetermined number of wires 252. However, in this configuration, light reflected by the uncovered wires 252 may be incident on the pixels as unnecessary light. The semiconductor package 200 according to a first modification example of the first embodiment is different from that of the first embodiment in that the frame 210 covers all the wires 252 to block unnecessary light.

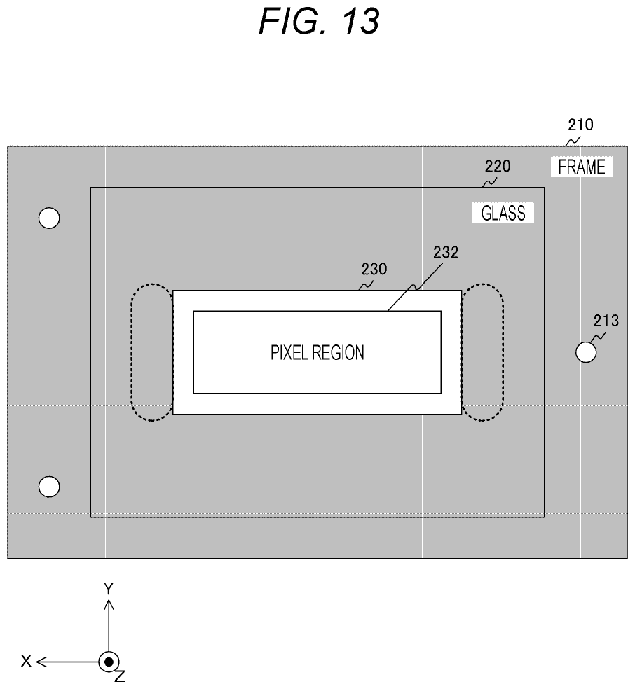

FIG. 13 is an example of a plan view of the semiconductor package 200 according to the first modification example of the first embodiment of the present technology. Portions surrounded by dotted lines in FIG. 13 indicate portions of the wires 252 that are not covered in the first embodiment.

As illustrated in FIG. 13, the frame 210 in the first modification example of the first embodiment further covers the wires 252 in the dotted line portions as seen from the Z-axis direction. Therefore, the circuit regions 231 and all the wires 252 are covered with the frame 210 except for the pixel region 232. Because the frame 210 covers all the wires 252, unnecessary light to the pixels can be blocked. Therefore, image quality of image data can be improved.

As described above, the frame 210 covers all the wires 252 in the first modification example of the first embodiment of the present technology, and thus it is possible to block unnecessary light to the pixels.

### Second Modification Example

In the above first embodiment, the extended portion 212 is provided in the frame 210. However, light reflected by an end surface of the extended portion 212 may be incident on the pixels to cause flares. The semiconductor package 200 according to a second modification example of the first embodiment is different from that of the first embodiment in that the end surface is tapered to suppress flares.

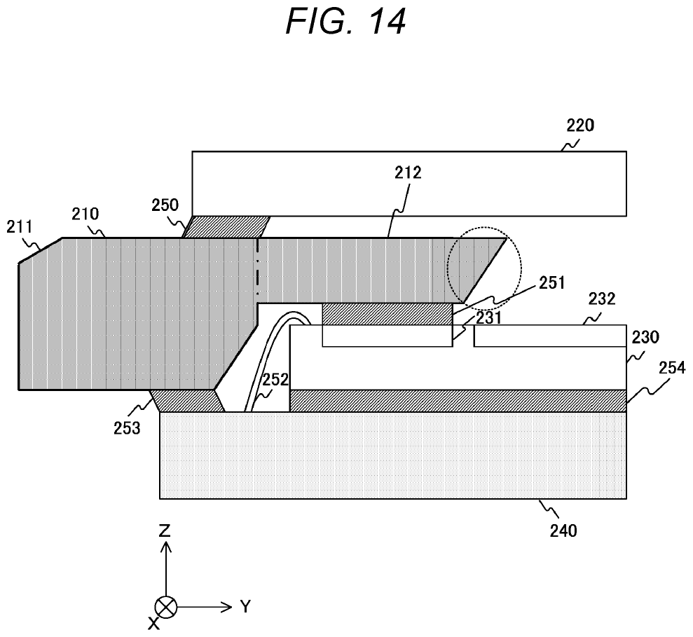

FIG. 14 is an example of a cross-sectional view of the semiconductor package 200 according to the second modification example of the first embodiment of the present technology. In the second modification example of the first embodiment, an area of an upper surface of the extended portion 212 is larger than an area of a lower surface bonded to the circuit region 231. Therefore, a diameter of an inner end portion of the extended portion 212 decreases toward the upper side as illustrated in FIG. 14. Such a shape of the end surface is called a tapered shape. Because the end surface of the extended portion 212 is formed in a tapered shape, light reflected by the end surface is not incident on the pixels. This makes it possible to suppress flares caused by the reflected light.

Note that the second modification example can also be applied to the first modification example of the first embodiment.

As described above, according to the second modification example of the first embodiment of the present technology, the end surface of the extended portion 212 is formed in a tapered shape, and thus light reflected by the end surface is not incident on the pixels. Therefore, it is possible to suppress flares caused by the reflected light.

### 2. Second Embodiment

In the above first embodiment, the circuit region 231 is provided in the sensor chip 230. However, the circuit region 231 expands with the increase in a circuit scale of the sensor chip in recent years, and optimization of a characteristic and chip size is a problem. The semiconductor package 200 of a second embodiment is different from that of the first embodiment in that the circuit scale of the sensor chip 230 is reduced by using a chip on chip (CoC) structure.

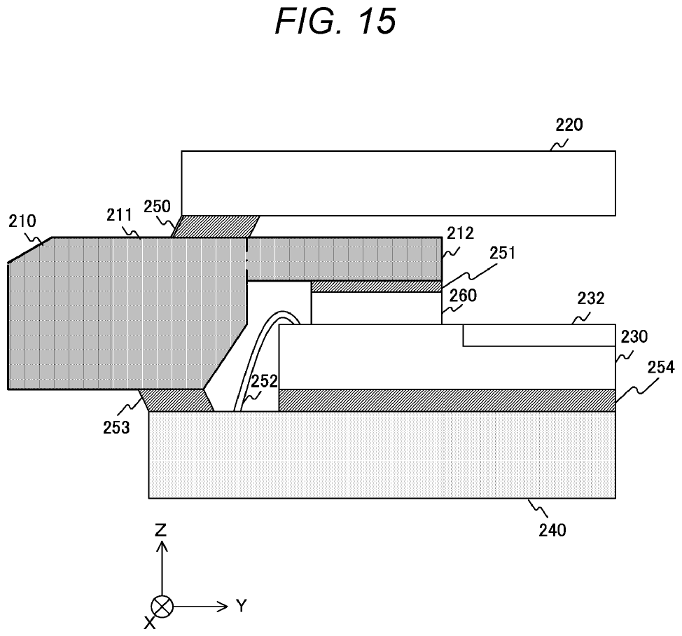

FIG. 15 is an example of a cross-sectional view of the semiconductor package 200 according to the second embodiment of the present technology. The semiconductor package 200 of the second embodiment is different from that of the first embodiment in further including a circuit chip 260. Further, the circuit regions 231 are removed from the sensor chip 230 of the second embodiment.

The circuit chip 260 includes circuits (a drive circuit, a signal processing circuit, and the like) similar to the circuits in the circuit region 231 of the first embodiment. The circuit chip 260 is stacked in a region where the pixel region 232 is not formed on the upper surface (in other words, the light receiving surface) of the sensor chip 230. Further, an upper surface of the circuit chip 260 is bonded to the extended portion 212 with the adhesive 251. As illustrated in FIG. 15, a structure in which a chip is connected to another chip is called a chip on chip (CoC) structure.

By using the chip on chip (CoC) structure, the circuit regions 231 can be removed from the sensor chip 230. Further, also in the chip on chip (CoC) structure, heat of the circuit chip 260 can be dissipated through the frame 210.

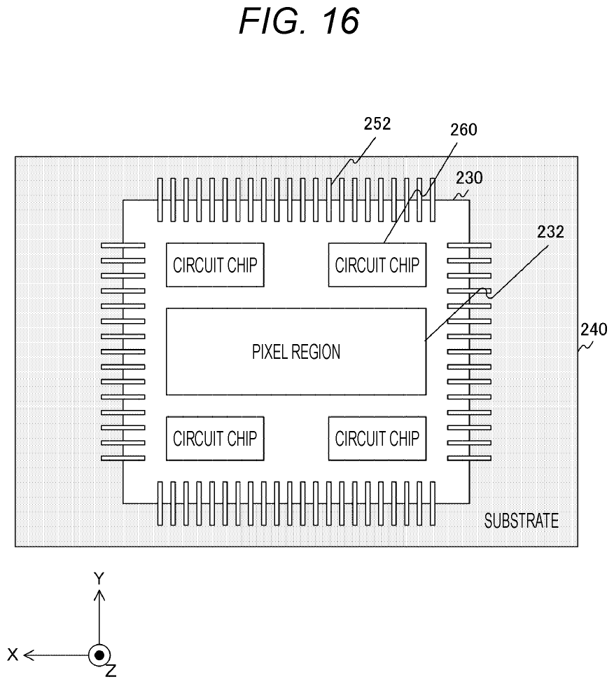

FIG. 16 is an example of a plan view of the semiconductor package 200 according to the second embodiment of the present technology. FIG. 16 illustrates a plan view of a state before mounting the frame 210. As illustrated in FIG. 16, a predetermined number of circuit chips 260 are stacked in a region adjacent to the pixel region 232 on the upper surface of the sensor chip 230.

As described above, according to the second embodiment of the present technology, the circuit chips 260 are stacked on the sensor chip 230, and thus the circuit scale of the sensor chip 230 can be reduced.

### 3. Third Embodiment

In the above second embodiment, the frame 210 made from resin or the like is used, but the heat dissipation performance may be insufficient with only resin. A third embodiment is different from the second embodiment in that the frame 210 of the third embodiment is made from resin and metal.

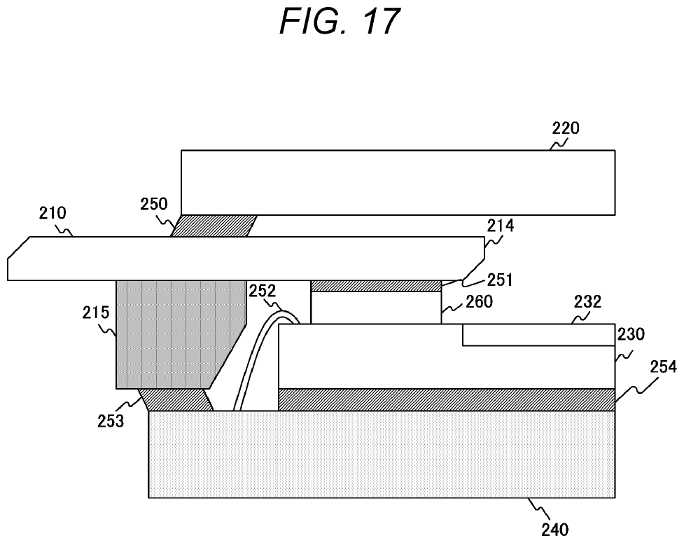

FIG. 17 is an example of a cross-sectional view of the semiconductor package 200 according to the third embodiment of the present technology. The semiconductor package 200 of the third embodiment is different from that of the first embodiment in that the frame 210 is made from resin and metal. Note that the entire frame 210 may also be made from metal without using resin.

In the frame 210, a portion surrounding the outer periphery of the sensor chip 230 is made from resin, and the portion is referred to as a resin portion 215. Further, a portion other than the resin portion 215 of the frame 210 is made from metal, and the portion is referred to as a metal portion 214. One end of the metal portion 214 reaches the outside of the resin portion 215. Further, the metal portion 214 is bonded to the circuit chip 260 with the adhesive 251.

As illustrated in FIG. 17, the frame 210 includes the resin portion 215 and the metal portion 214, and thus the heat dissipation performance can be improved, as compared with the first embodiment in which the frame 210 is made from resin only.

As described above, according to the third embodiment of the present technology, the frame 210 includes the resin portion 215 and the metal portion 214, and thus the heat dissipation performance can be improved, as compared with a case where the frame 210 is made from resin only.

### 4. Fourth Embodiment

In the above second embodiment, a part of the inner wall of the frame 210 is extended to bond the extended portion 212 to the circuit region 231. However, in this configuration, the extended portion 212 has a lower degree of freedom in shape and also has a lower elastic modulus. Thus, in some cases, it is difficult to eliminate variations in a position of each portion at the time of mounting. The semiconductor package 200 according to a fourth embodiment is different from that of the second embodiment in that variations in the position is easily eliminated by using a heat dissipation sheet.

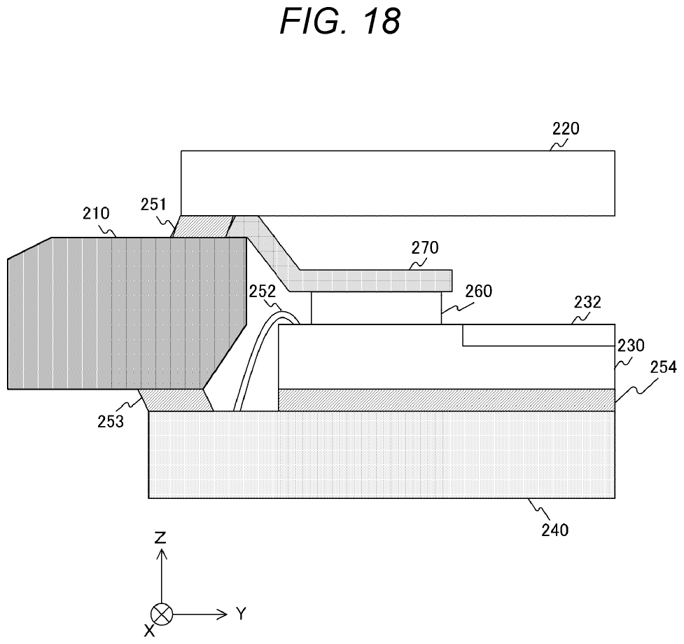

FIG. 18 is an example of a cross-sectional view of the semiconductor package 200 according to the fourth embodiment of the present technology. The semiconductor package 200 of the fourth embodiment is different from that of the second embodiment in further including a heat dissipation sheet 270. Further, the frame 210 of the fourth embodiment does not include the extended portion 212. Note that, although the heat dissipation sheet 270 is provided in the CoC structure, the heat dissipation sheet 270 may also be provided in a structure other than the CoC structure (the first embodiment or the like). The same applies to each configuration including the heat dissipation sheet 270 in a fifth and subsequent embodiments.

The heat dissipation sheet 270 is a sheet-like member having a lower elastic modulus than the frame 210. When seen from the X-axis direction and the Y-axis direction, one end of the heat dissipation sheet 270 is bonded to a portion where the frame 210 and the glass 220 are bonded. Further, a part of the heat dissipation sheet 270 is bonded to the upper surface of the circuit chip 260 with an adhesive (not illustrated). Because the heat dissipation sheet 270 has a higher degree of freedom in shape and a lower elastic modulus than the frame 210, the use of the heat dissipation sheet 270 makes it easy to absorb variations in the position of each portion occurring at the time of manufacturing the semiconductor package 200.

As described above, in the fourth embodiment of the present technology, the heat dissipation sheet 270 having a high degree of freedom in shape is bonded to the circuit chip 260, and thus variations in the position of each portion can be easily eliminated, as compared with a case where the frame 210 is bonded to the circuit chip 260.

### 5. Fifth Embodiment

In the above fourth embodiment, one end of the heat dissipation sheet 270 is bonded to the portion where the frame 210 and the glass 220 are bonded. However, the one end of the heat dissipation sheet 270 can also be extended to the outside of the frame 210. The semiconductor package 200 of the fifth embodiment is different from that of the fourth embodiment in that one end of the heat dissipation sheet 270 is extended to the outside of the frame 210.

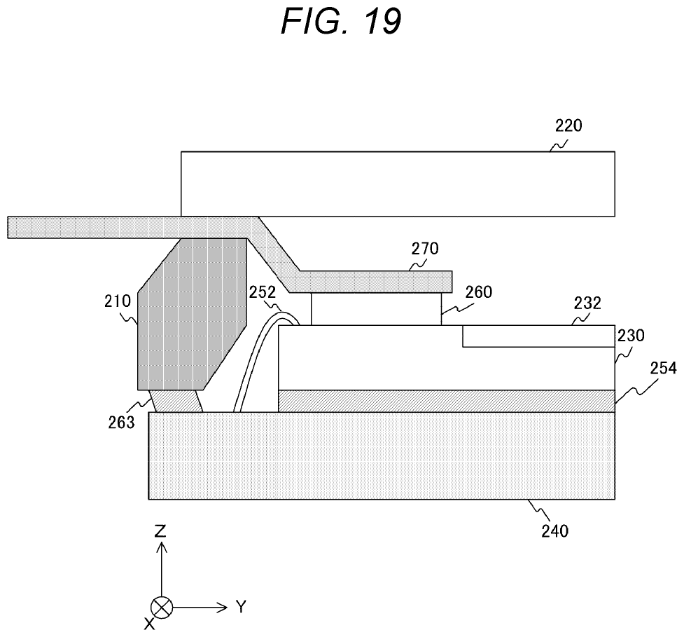

FIG. 19 is an example of a cross-sectional view of the semiconductor package 200 according to the fifth embodiment of the present technology. The semiconductor package 200 of the fifth embodiment is different from that of the fourth embodiment in that the one end of the heat dissipation sheet 270 is extended to the outside of the frame 210. A part of a lower surface of the heat dissipation sheet 270 is bonded to the frame 210 with an adhesive (not illustrated), and a part of an upper surface thereof is bonded to the glass 220. This eliminates the need for bonding the one end of the heat dissipation sheet 270 to the portion where the frame 210 and the glass 220 are bonded.

As described above, according to the fifth embodiment of the present technology, the one end of the heat dissipation sheet 270 is extended to the outside of the frame 210, and this eliminates the need for bonding the one end thereof to the portion where the frame 210 and the glass 220 are bonded.

### 6. Sixth Embodiment

In the above fourth embodiment, the one end of the heat dissipation sheet 270 is bonded to the portion where the frame 210 and the glass 220 are bonded. However, in this configuration, heat cannot be dissipated from the heat dissipation sheet 270 to the substrate 240. The semiconductor package 200 of a sixth embodiment is different from that of the fourth embodiment in that the one end of the heat dissipation sheet 270 is bonded to the substrate 240.

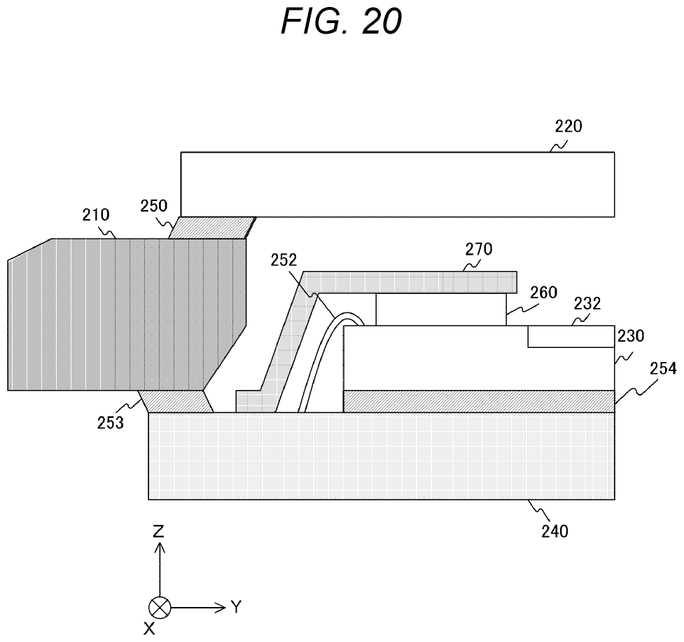

FIG. 20 is an example of a cross-sectional view of the semiconductor package 200 according to the sixth embodiment of the present technology. The semiconductor package 200 of the sixth embodiment is different from that of the fourth embodiment in that the one end of the heat dissipation sheet 270 is bonded to the substrate 240. Further, in the sixth embodiment, a part of the heat dissipation sheet 270 is bonded to the upper surface of the circuit chip 260 as in the fourth embodiment.

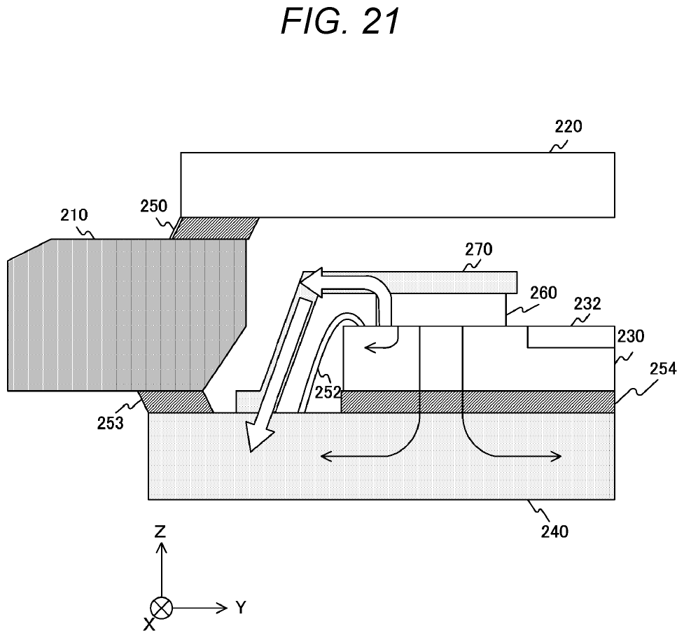

FIG. 21 illustrates an example of a heat dissipation path of the semiconductor package 200 according to the sixth embodiment of the present technology. As illustrated in FIG. 21, the circuit chip 260 generates heat when the sensor chip 230 (in other words, the solid-state imaging element) operates. The stacked circuit chip 260 is in contact with the sensor chip 230 and the heat dissipation sheet 270, and the heat dissipation sheet 270 having a high thermal conductivity is selected to conduct the heat of the circuit chip 260 to the heat dissipation sheet 270 as much as possible, thereby reducing conduction of the heat to the sensor chip 230. Therefore, the heat conducted to the sensor chip 230 is reduced to reduce an influence on the pixel region 232, and deterioration or destruction of the pixels is less likely to occur.

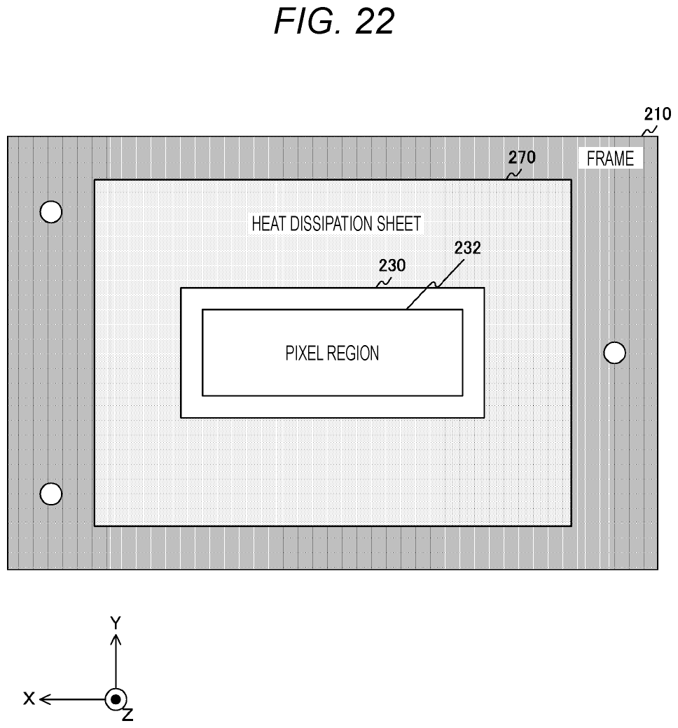

FIG. 22 is an example of a plan view of the semiconductor package 200 according to the sixth embodiment of the present technology. As illustrated in FIG. 22, the heat dissipation sheet 270 can be formed to cover portions other than the pixel region 232, such as the wires 252 and the circuit regions 231, depending on required specifications. Therefore, it is possible to achieve not only high heat dissipation performance, but also unnecessary light blocking performance. However, it is necessary to provide an area for bonding the heat dissipation sheet 270 outside the wires 252, and an increase in size of the substrate 240 is required.

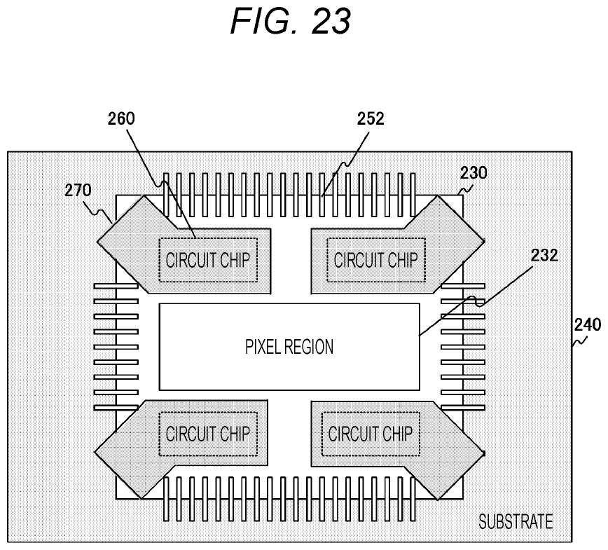

Note that, as illustrated in FIG. 23, when the heat dissipation sheet 270 is bonded to the substrate 240 at a portion where no wire 252 is provided, such as a corner, it is unnecessary to increase the size of the substrate 240.

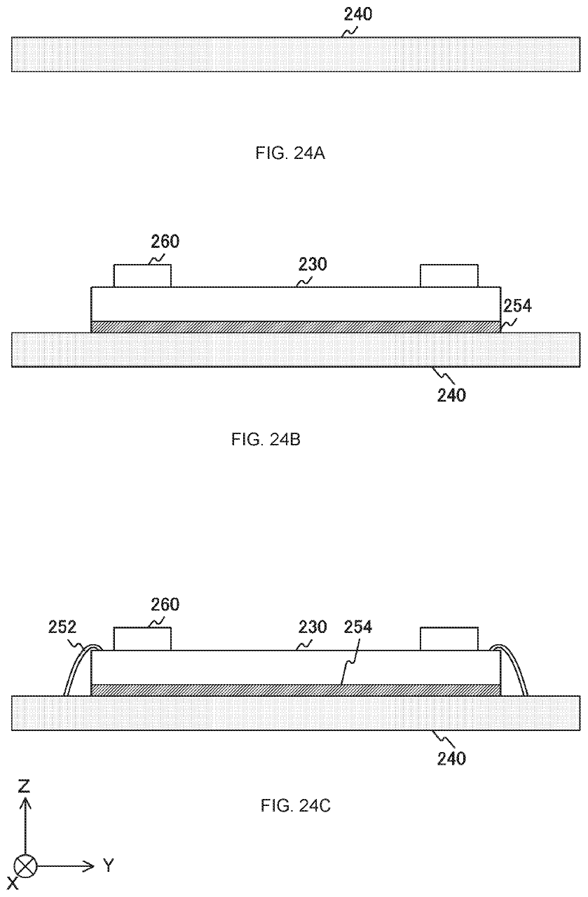

FIG. 24 is an example of a cross-sectional view illustrating a method of manufacturing the semiconductor package 200 up to mounting of the heat dissipation sheet 270 in the sixth embodiment of the present technology. In FIG. 24, a is an example of a cross-sectional view of the substrate 240 before bonding the sensor chip 230. In FIG. 24, b is an example of a cross-sectional view of the semiconductor package 200 after bonding the sensor chip 230 and before wire bonding. In FIG. 24, c is an example of a cross-sectional view of the semiconductor package 200 after the wire bonding. Steps until the wire bonding in the sixth embodiment are similar to those in the first embodiment.

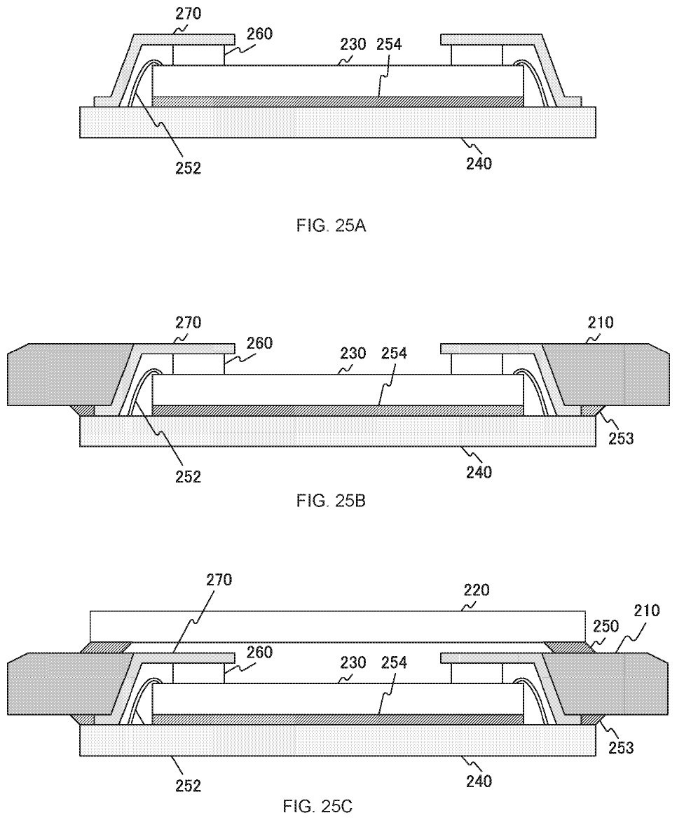

FIG. 25 is an example of a cross-sectional view illustrating the method of manufacturing the semiconductor package 200 up to bonding of the glass 220 in the sixth embodiment of the present technology. In FIG. 25, a is an example of a cross-sectional view of the semiconductor package 200 after bonding the heat dissipation sheet 270 and before bonding the frame 210. In FIG. 25, b is an example of a cross-sectional view of the semiconductor package 200 after bonding the frame 210 and before bonding the glass 220. In FIG. 25, c is an example of a cross-sectional view of the semiconductor package 200 after bonding the glass 220.

As illustrated in a of FIG. 25, the manufacturing system bonds the heat dissipation sheets 270 to the circuit chips 260 and the substrate 240.

Then, the manufacturing system mounts the frame 210 by applying an adhesive to the substrate 240 as illustrated in b of FIG. 25 and mounts the glass 220 by applying an adhesive to the frame 210 as illustrated in c of FIG. 25.

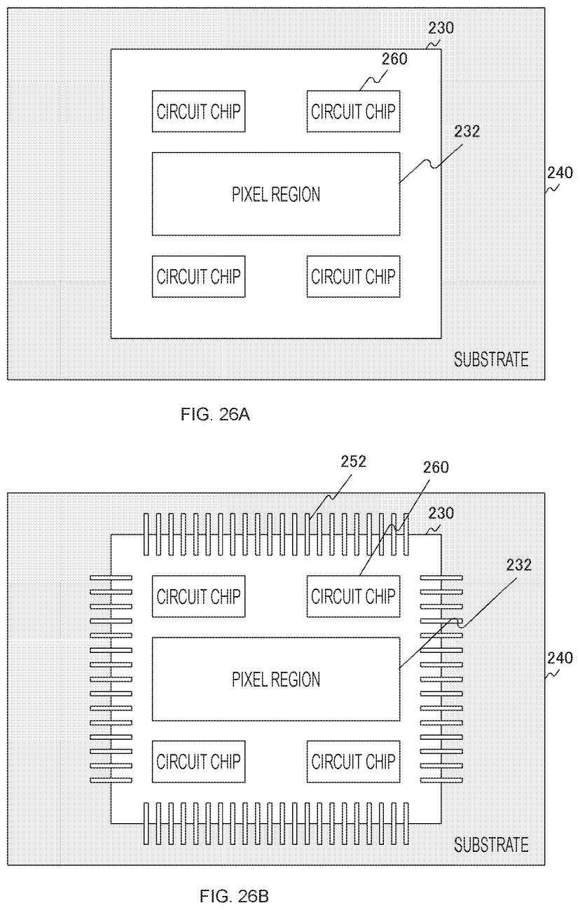

FIG. 26 is an example of a plan view illustrating the method of manufacturing the semiconductor package 200 up to the wire bonding in the sixth embodiment of the present technology. In FIG. 26, a is an example of a plan view of the semiconductor package 200 after bonding the sensor chip 230 and before the wire bonding. In FIG. 26, b is an example of a plan view of the semiconductor package 200 after the wire bonding. Steps until the wire bonding in the sixth embodiment are similar to those in the first embodiment.

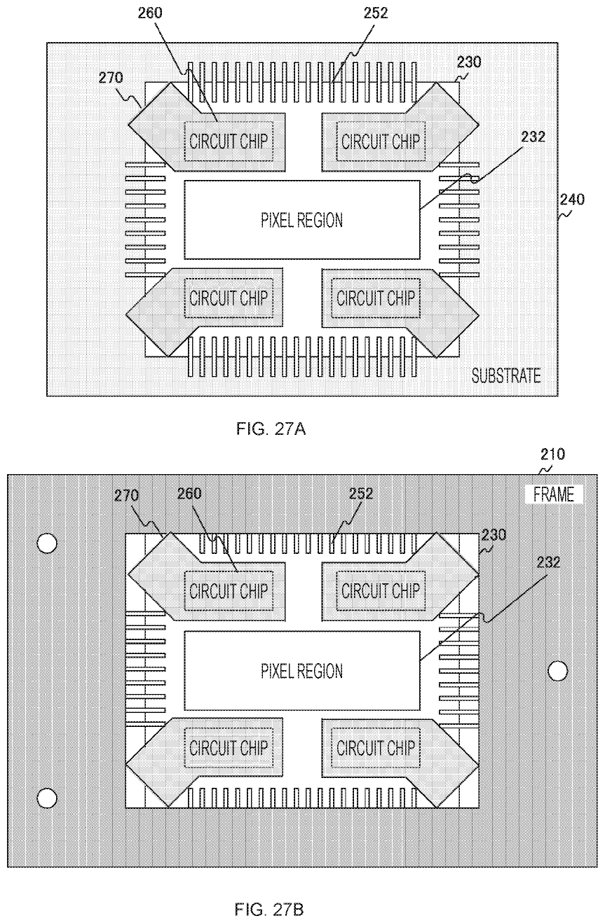

FIG. 27 is an example of a plan view illustrating the method of manufacturing the semiconductor package up to the mounting of the frame 210 in the sixth embodiment of the present technology. In FIG. 27, a is an example of a cross-sectional view of the semiconductor package 200 after bonding the heat dissipation sheets 270 and before bonding the frame 210. In FIG. 27, b is an example of a cross-sectional view of the semiconductor package 200 after bonding the frame 210.

As illustrated in a of FIG. 27, the manufacturing system bonds the heat dissipation sheets 270 to the circuit chips 260 and the substrate 240. For example, four circuit chips 260 are provided, and the heat dissipation sheet 270 is bonded to each of the circuit chips. In this configuration, the number of heat dissipation sheets 270 is four.

Then, as illustrated in b of FIG. 27, the manufacturing system mounts the frame 210 on the substrate 240.

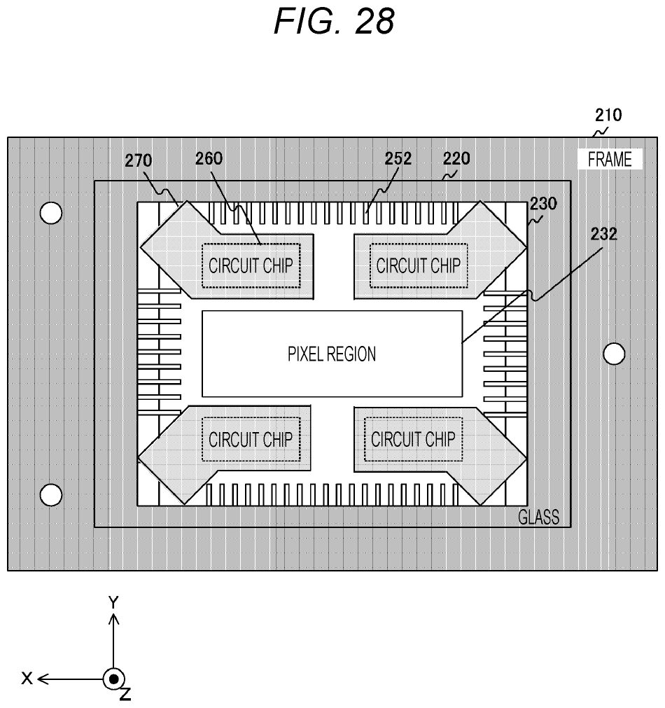

FIG. 28 is an example of a cross-sectional view illustrating the method of manufacturing the semiconductor package at the time of bonding the glass 220 in the sixth embodiment of the present technology. As illustrated in FIG. 28, the manufacturing system mounts the glass 220 on the frame 210.

As described above, according to the sixth embodiment of the present technology, the one end of the heat dissipation sheet 270 is bonded to the substrate 240, and thus heat generated in the circuit chip 260 can be dissipated to the substrate 240 through the heat dissipation sheet 270.

### First Modification Example

In the above sixth embodiment, a part of the heat dissipation sheet 270 is bonded to the upper surface of the circuit chip 260. However, in this configuration, light reflected by a side surface of the circuit chip 260 may be incident on the pixels to cause flares. The semiconductor package 200 according to a first modification example of the sixth embodiment is different from that of the sixth embodiment in that the upper surface and side surface of the circuit chip 260 are covered with the heat dissipation sheet 270 to suppress flares.

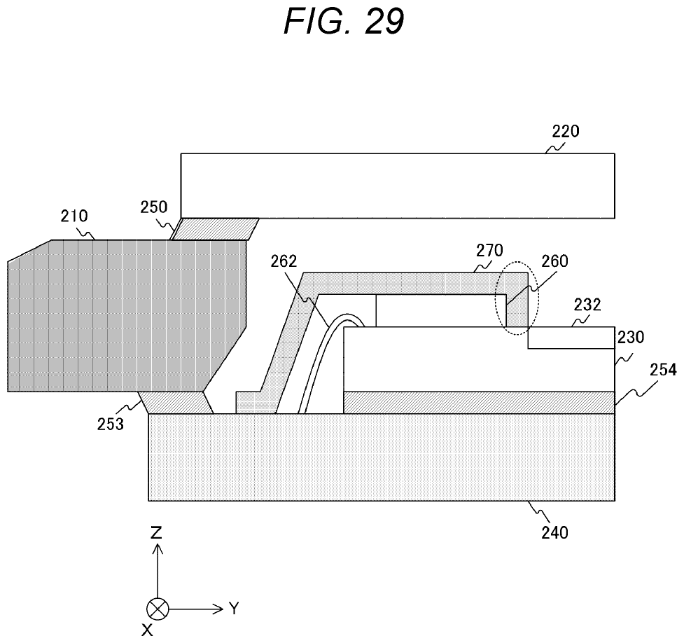

FIG. 29 is an example of a cross-sectional view of the semiconductor package 200 according to the first modification example of the sixth embodiment of the present technology. The semiconductor package 200 according to the first modification example of the sixth embodiment is different from that of the sixth embodiment in that not only the upper surface of the circuit chip 260 but also an inner side surface thereof is covered with the heat dissipation sheet 270. Because the side surface of the circuit chip 260 is also covered with the heat dissipation sheet 270, it is possible to prevent reflection of light on the side surface. Therefore, it is possible to suppress flares caused by unnecessary light reflected on the side surface.

As described above, in the first modification example of the sixth embodiment of the present technology, the heat dissipation sheet 270 covers the upper surface and side surface of the circuit chip 260, and thus it is possible to suppress flares caused by reflection of light on the side surface.

### Second Modification Example

In the above sixth embodiment, the four circuit chips 260 are covered with the four heat dissipation sheets 270. However, the number of heat dissipation sheets 270 is desirably small. The semiconductor package 200 according to a second modification example of the sixth embodiment is different from that of the sixth embodiment in that the number of heat dissipation sheets 270 is reduced.

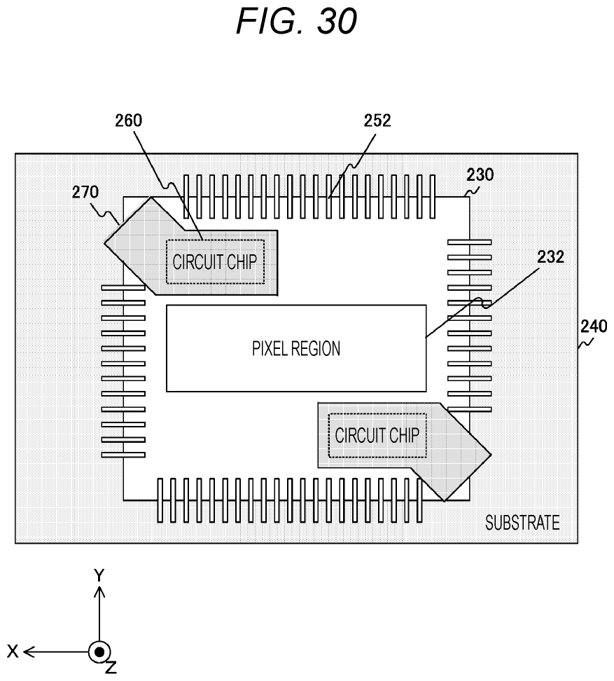

FIG. 30 is an example of a plan view of the semiconductor package 200 according to the second modification example of the sixth embodiment of the present technology. For example, as illustrated in FIG. 30, the number of circuit chips 260 can be two. In this case, the number of heat dissipation sheets 270 is also only two.

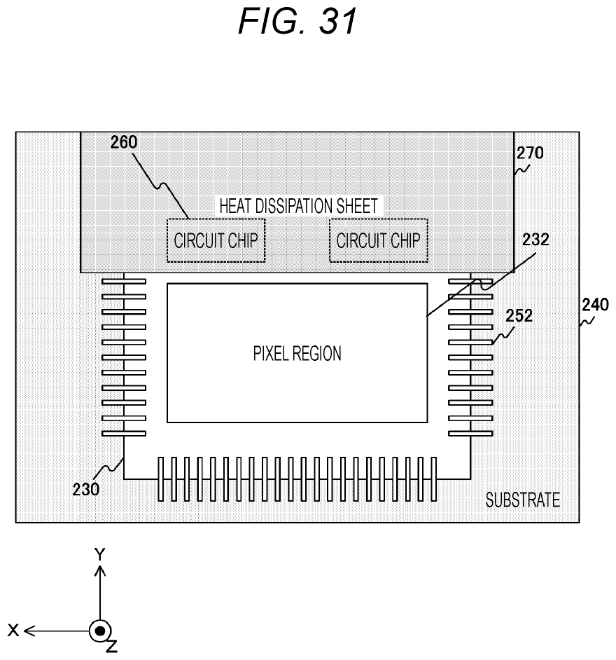

Further, as illustrated in FIG. 31, the two circuit chips 260 can also be covered with one heat dissipation sheet 270.

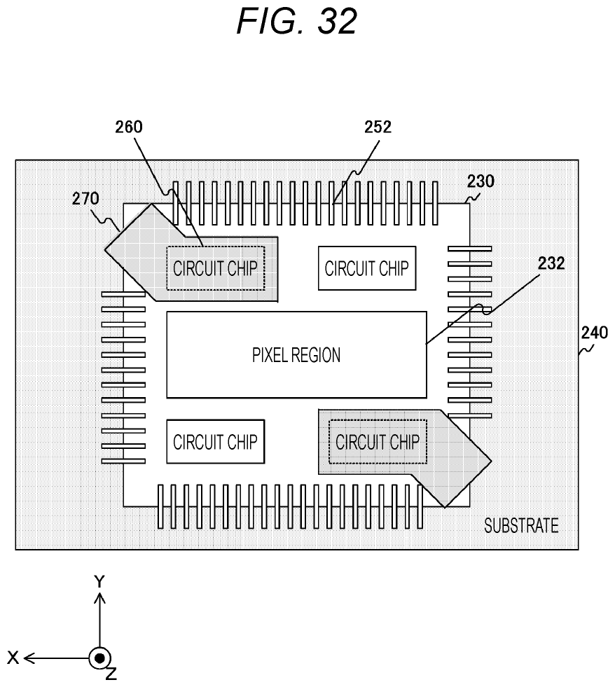

Further, as illustrated in FIG. 32, some of a plurality of circuit chips 260 may also be covered with the heat dissipation sheets 270. For example, only two of the four circuit chips 260 can be covered with two heat dissipation sheets 270. The circuit chip 260 to be covered with the heat dissipation sheet 270 is appropriately selected according to a heat generation level of the chip.

By reducing the number of heat dissipation sheets 270 as illustrated in FIGS. 30 to 32, the number of fixtures of the semiconductor package 200 can be reduced.

Note that the second modification example can also be applied to the first modification example of the sixth embodiment.

As described above, according to the second modification example of the sixth embodiment of the present technology, the number of heat dissipation sheets 270 is reduced, and thus the number of fixtures of the semiconductor package 200 can be reduced accordingly.

### 7. Seventh Embodiment

In the above sixth embodiment, the organic substrate (substrate 240) is used. However, in this configuration, bonding of the heat dissipation sheet 270 to the substrate 240 may become difficult. The semiconductor package 200 according to a seventh embodiment is different from that of the sixth embodiment in that a ceramic substrate is used and a step for bonding the heat dissipation sheet 270 is provided.

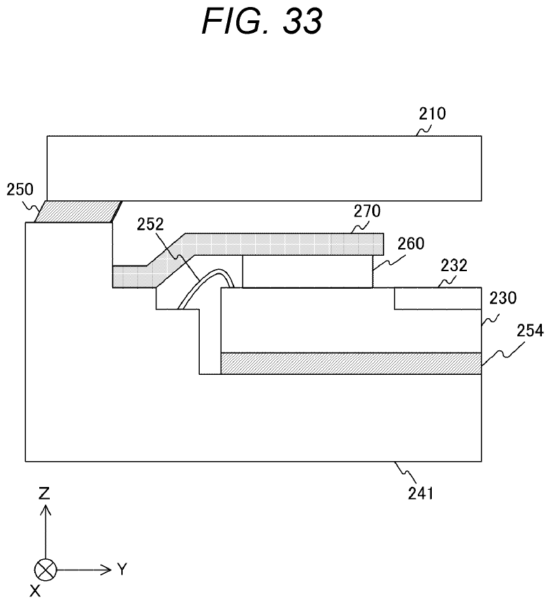

FIG. 33 is an example of a cross-sectional view of the semiconductor package 200 according to the seventh embodiment of the present technology. The semiconductor package 200 according to the seventh embodiment is different from that of the sixth embodiment in including a ceramic substrate 241 instead of the organic substrate (substrate 240).

In the ceramic substrate 241, an inner wall of a cavity can be easily formed in a stepwise manner. For example, in FIG. 33, two steps are provided on the inner wall of the ceramic substrate 241, and a pad for connecting the wire 252 is provided in the first step, whereas one end of the heat dissipation sheet 270 is bonded in the second step. As described above, the one end of the heat dissipation sheet 270 is bonded in a step different from a step for connecting the wire 252, and thus it is unnecessary to avoid the pad when bonding the one end of the heat dissipation sheet 270. Therefore, bonding can be easily performed.

Note that the present technology is not limited to each of the above embodiments, and various configurations are conceivable for the heat dissipation path by combining a heat dissipation material and a heat dissipation destination exemplified below. As the heat dissipation material, resin, metal, and a heat dissipation sheet are exemplified in the above embodiment. However, a Peltier element, a flexible substrate, a nanocapillary, a leaf spring, a heat pipe, or the like can also be used.

Further, the heat dissipation destination from a back surface of a laminated chip can be the frame, the organic substrate, the ceramic substrate, or the outside of the semiconductor package 200 as described in the above embodiments.

A more suitable combination can be selected from the heat dissipation materials and heat dissipation destinations described above depending on a characteristic of the solid-state imaging element to be applied, size restriction of the semiconductor device, required economic efficiency, or the like.

As described above, in the seventh embodiment of the present technology, the ceramic substrate 241 having a stepped inner wall is provided, and thus one end of the heat dissipation sheet 270 can be bonded to a step different from a step for connecting the wire 252. Therefore, the heat dissipation sheet 270 can be easily bonded.

### 8. Application Example to Mobile Body

The technology according to the present disclosure (present technology) can be applied to various products. For example, the technology according to the present disclosure may be implemented as a device mounted on any type of mobile body such as an automobile, an electric vehicle, a hybrid electric vehicle, a motorcycle, a bicycle, a personal mobility, an airplane, a drone, a ship, or a robot.

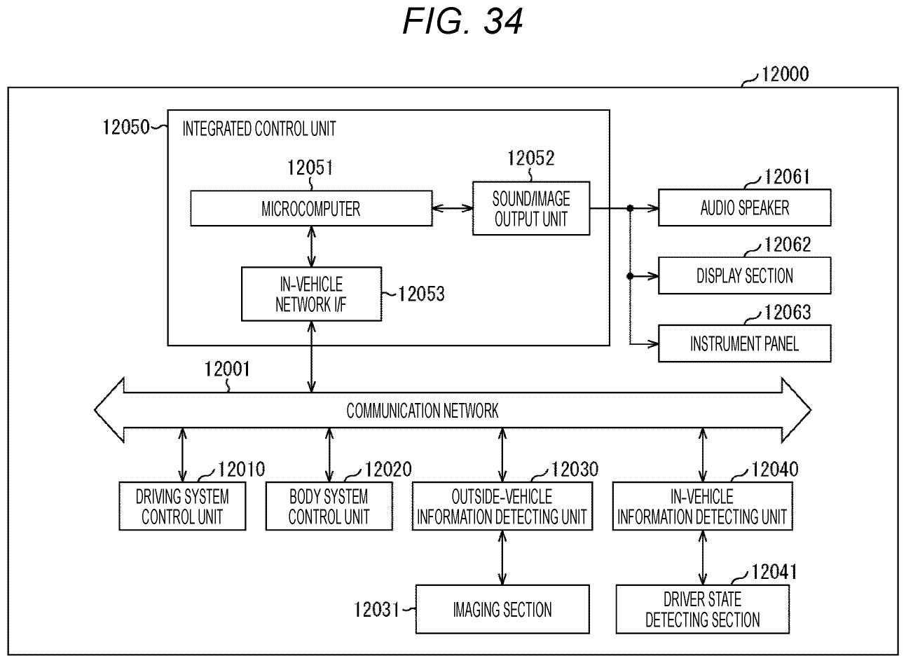

FIG. 34 is a block diagram illustrating a schematic configuration example of a vehicle control system that is an example of a mobile body control system to which the technology according to the present disclosure can be applied.

The vehicle control system 12000 includes a plurality of electronic control units connected to each other via a communication network 12001. In the example of FIG. 34, the vehicle control system 12000 includes a driving system control unit 12010, a body system control unit 12020, an outside-vehicle information detecting unit 12030, an in-vehicle information detecting unit 12040, and an integrated control unit 12050. Further, a microcomputer 12051, a sound/image output unit 12052, and an in-vehicle network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Further, the microcomputer 12051 can output a control command to the body system control unit 12020 on the basis of information regarding the outside of the vehicle, the information being acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 34, an audio speaker 12061, a display section 12062, and an instrument panel 12063 are illustrated as the output device. The display section 12062 may, for example, include at least one of an on-board display and a head-up display.

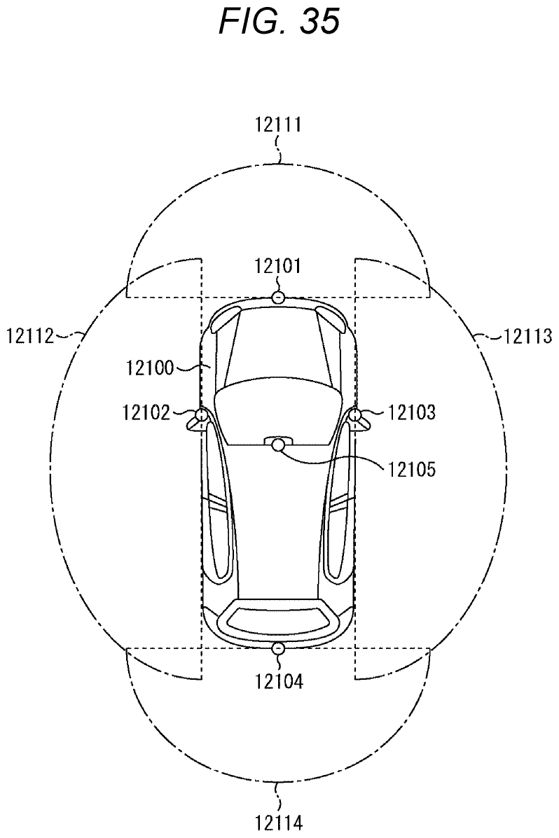

FIG. 35 illustrates an example of an installation position of the imaging section 12031.

In FIG. 35, the imaging section 12031 includes imaging sections 12101, 12102, 12103, 12104, and 12105.

The imaging sections 12101, 12102, 12103, 12104, and 12105 are provided at, for example, positions on a front nose, sideview mirrors, a rear bumper, and a back door of a vehicle 12100, an upper portion of a windshield within the interior of the vehicle, and the like. The imaging section 12101 provided to the front nose and the imaging section 12105 provided to the upper portion of the windshield within the interior of the vehicle obtain mainly an image of the front of the vehicle 12100. The imaging sections 12102 and 12103 provided on the sideview mirrors mainly acquire images of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 35 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to, for example, the imaging section 12031 in the configuration described above. Specifically, the electronic device 100 in FIG. 1 can be applied to the imaging section 12031. By applying the technology according to the present disclosure to the imaging section 12031, it is possible to suppress deterioration in image quality caused by heat and to obtain a clearer captured image. Thus, it is possible to reduce driver's fatigue.

Note that, the above embodiments show examples for embodying the present technology, and matters in the embodiments and matters specifying the invention in claims have correspondence relationships. Similarly, the matters specifying the invention in claims and the matters in the embodiments of the present technology having the same names have correspondence relationships. However, the present technology is not limited to the embodiments and may be embodied by variously modifying the embodiments without departing from the scope thereof.

Note that the effects described in the present specification are merely examples and are not limited, and other effects may be obtained.

Note that the present technology can also have the following configurations.

(1)

A semiconductor package including:
a solid-state imaging element having a pixel region in which pixels are arrayed and a circuit region in which a predetermined circuit is arranged adjacent to the pixel region;
a frame whose inner wall surrounding an outer periphery of the solid-state imaging element is partially extended inward;
and an adhesive for bonding the extended portion of the frame and the circuit region.

(2)

The semiconductor package according to (1), further including:
a substrate; and
a predetermined number of wires that connect the substrate and the solid-state imaging element.

(3)

The semiconductor package according to (2), in which
the frame covers some of the wires and the circuit region.

(4)

The semiconductor package according to (3), in which the frame further covers the remaining wires.

(5)

The semiconductor package according to any one of (1) to (4), in which
the extended portion of the frame has a tapered end surface.

(6)

A method of manufacturing a semiconductor package, the method including:
a wire bonding step of connecting a solid-state imaging element to a substrate by a wire, the solid-state imaging element having a pixel region in which pixels are arrayed and a circuit region in which a predetermined circuit is arranged adjacent to the pixel region; and
a bonding step of bonding, with an adhesive, the circuit region and an extended portion of a frame whose inner wall surrounding an outer periphery of the solid-state imaging element is partially extended inward.

(7)

An electronic device including:
a solid-state imaging element having a pixel region in which pixels are arrayed and a circuit region in which a predetermined circuit is arranged adjacent to the pixel region;
a frame whose inner wall surrounding an outer periphery of the solid-state imaging element is partially extended inward;
an adhesive for bonding the extended portion of the frame and the circuit region; and
an optical unit that collects light and guides the light to the solid-state imaging element.

(8)

A semiconductor package including:
a solid-state imaging element;
a circuit chip stacked on the solid-state imaging element;
a frame whose inner wall surrounding an outer periphery of the solid-state imaging element is partially extended inward; and
an adhesive for bonding the extended portion of the frame and the circuit chip.

(9)

A semiconductor package including:
a solid-state imaging element;
a circuit chip stacked on the solid-state imaging element;
a frame including a resin portion surrounding an outer periphery of the solid-state imaging element and a metal portion having one end reaching the outside of the resin portion; and
an adhesive for bonding a part of the metal portion and the circuit chip.

(10)

A semiconductor package including:
a solid-state imaging element;
a circuit chip stacked on the solid-state imaging element;
a frame surrounding an outer periphery of the solid-state imaging element; and
a heat dissipation sheet bonded to the circuit chip and having one end reaching the outside of the frame.

(11)

A semiconductor package including:
a solid-state imaging element;
a circuit chip having a lower surface connected to the solid-state imaging element;
a frame surrounding an outer periphery of the solid-state imaging element; and
a heat dissipation sheet covering an upper surface and side surface of the circuit chip.

(12)

A semiconductor package including:
a solid-state imaging element;
a plurality of circuit chips stacked on the solid-state imaging element;
a frame surrounding an outer periphery of the solid-state imaging element; and
a heat dissipation sheet covering some of the plurality of circuit chips.

### REFERENCE SIGNS LIST

100 Electronic device
110 Optical unit
120 DSP circuit
130 Display unit
140 Operation unit
150 Bus
160 Frame memory
170 Storage unit
180 Power supply unit
200 Semiconductor package
210 Frame
211 Outer peripheral portion
212 Extended portion
214 Metal portion
215 Resin portion
220 Glass
230 Sensor chip
231 Circuit region
232 Pixel region
240 Substrate
241 Ceramic substrate
250, 251, 253, 254 Adhesive
252 Wire
260 Circuit chip
270 Heat dissipation sheet
12031 Imaging section

1. A semiconductor package comprising:
a solid-state imaging element having a pixel region in which pixels are arrayed and a circuit region in which a predetermined circuit is arranged adjacent to the pixel region;
a frame whose inner wall surrounding an outer periphery of the solid-state imaging element is partially extended inward; and
an adhesive for bonding the extended portion of the frame and the circuit region.

2. The semiconductor package according to claim 1, further comprising:
a substrate; and
a predetermined number of wires that connect the substrate and the solid-state imaging element.

3. The semiconductor package according to claim 2, wherein the frame covers some of the wires and the circuit region.

4. The semiconductor package according to claim 3, wherein the frame further covers the remaining wires.

5. The semiconductor package according to claim 1, wherein the extended portion of the frame has a tapered end surface.

6. A method of manufacturing a semiconductor package, the method comprising:
a wire bonding step of connecting a solid-state imaging element to a substrate by a wire, the solid-state imaging element having a pixel region in which pixels are arrayed and a circuit region in which a predetermined circuit is arranged adjacent to the pixel region; and
a bonding step of bonding, with an adhesive, the circuit region and an extended portion of a frame whose inner wall surrounding an outer periphery of the solid-state imaging element is partially extended inward.

7. An electronic device comprising:
a solid-state imaging element having a pixel region in which pixels are arrayed and a circuit region in which a predetermined circuit is arranged adjacent to the pixel region;
a frame whose inner wall surrounding an outer periphery of the solid-state imaging element is partially extended inward;
an adhesive for bonding the extended portion of the frame and the circuit region; and
an optical unit that collects light and guides the light to the solid-state imaging element.
